(19) United States
(12) Patent Application Publication
(10) Pub. No.: US 2005/0286234 A1
(43) Pub. Date: Dec. 29, 2005

(54) Thermally conductive composite interface and methods of fabrication thereof for an electronic assembly

(75) Inventors: Levi A. Campbell, New Paltz, NY (US); Richard C. Chu, Hopewell Junction, NY (US); Michael J. Ellsworth JR., Lagrangeville, NY (US); Madhusudan K. Iyengar, Rhinebeck, NY (US); Roger R. Schmidt, Poughkeepsie, NY (US); Robert E. Simons, Poughkeepsie, NY (US)

Correspondence Address: HESLIN ROTHENBERG FARLEY & MESITI P.C., 5 COLUMBIA CIRCLE, ALBANY, NY, 12203, US

(73) Assignee: International Business Machines Corporation, Armonk, NY (US)

(21) Appl. No.: 10/880,398

(22) Filed: Jun. 29, 2004

(51) Int. Cl. H05K 7/20

(52) U.S. Cl. 361/719

(57) ABSTRACT

A thermally conductive composite interface and methods of fabrication are provided for coupling a cooling assembly and at least one electronic device. The interface includes a plurality of thermally conductive contacts for mechanically coupling the cooling assembly and electronic device, and an adhesive material at least partially surrounding the thermally conductive contacts. The thermally conductive contacts are made of a first material, which has a first thermal conductivity, and the adhesive material is a second material, which has a second thermal conductivity, with the first thermal conductivity being greater than the second thermal conductivity. The adhesive material rigidly bonds the cooling assembly and the at least one electronic device together, thereby relieving strain on the plurality of thermally conductive contacts resulting from a coefficient of thermal expansion mismatch between the cooling assembly and the at least one electronic device.

### FIELD OF THE INVENTION

The present invention relates to heat transfer mechanisms, and more particularly, to heat transfer mechanisms and cooling assemblies for removing heat generated by an electronic device. More particularly, the present invention relates to a thermally conductive composite interface, and methods of fabrication thereof, for coupling a cooling assembly to one or more electronic devices to be cooled.

### BACKGROUND OF THE INVENTION

As is known, operating electronic devices produce heat. This heat should be removed from the devices in order to maintain device junction temperatures within desirable limits, with failure to remove the heat thus produced resulting in increased device temperatures, potentially leading to thermal runaway conditions. Several trends in the electronics industry have combined to increase the importance of thermal management, including heat removal for electronic devices, including technologies where thermal management has traditionally been less of a concern, such as CMOS. In particular, the need for faster and more densely packed circuits has had a direct impact on the importance of thermal management. First, power dissipation, and therefore heat production, increases as device operating frequencies increase. Second, increased operating frequencies may be possible at lower device junction temperatures. Finally, as more and more devices are packed onto a single chip, power density (Watts/cm²) increases, resulting in the need to remove more power from a given size chip or module.

Existing cooling technology typically utilizes air or water to carry the heat away from the electronic device, and reject the heat to the ambient. Heat sinks with heat pipes or vapor chambers are commonly used air-cooling devices, while cold-plates are most predominant in water cooling. However, with both types of cooling assemblies, it is necessary to attach the cooling assembly to the electronic device. This attachment results in a thermal interface resistance between the cooling assembly and the electronic device. The cooling assembly is usually fabricated of a metal, such as aluminum or copper, whereas the electronic device is typically an integrated circuit chip comprising silicon. Under typical operating conditions, the interface coupling the electronic device and cooling assembly will experience thermal stresses, which result from the electronic device and the cooling assembly, undergoing differential thermal expansion. Thus, the interface coupling the electronic device and cooling assembly should fulfill the dual needs of providing an effective thermal path for heat dissipation, while also maintaining structural or mechanical integrity of the electronic assembly.

### SUMMARY OF THE INVENTION

The shortcomings of the prior art are overcome and additional advantages are provided through the provision of a thermally conductive composite interface for coupling a cooling assembly and at least one electronic device, wherein the cooling assembly and the at least one electronic device have a coefficient of thermal expansion mismatch. The thermally conductive composite interface includes a plurality of thermally conductive contacts for mechanically coupling the cooling assembly and the at least one electronic device. The plurality of thermally conductive contacts comprise a first material, which has a first thermal conductivity. The interface further includes an adhesive material at least partially surrounding the plurality of thermally conductive contacts for bonding the cooling assembly to the at least one electronic device when the interface is employed to mechanically couple the cooling assembly and the at least one electronic device. The adhesive material reduces strain on the plurality of thermally conductive contacts resulting from the coefficient of thermal expansion mismatch between the cooling assembly and the at least one electronic device. The adhesive material comprises a second material, with the second material having a second thermal conductivity and the first thermal conductivity of the first material being greater than the second thermal conductivity of the second material.

In another aspect, an electronic assembly is provided which includes at least one electronic device and a cooling assembly for the at least one electronic device, wherein the cooling assembly and the at least one electronic device have a coefficient of thermal expansion mismatch. A thermally conductive composite interface is provided coupling the cooling assembly and the at least one electronic device. The thermally conductive composite interface includes a plurality of thermally conductive contacts mechanically coupling the cooling assembly and the at least one electronic device, wherein the plurality of thermally conductive contacts comprise a first material having a first thermal conductivity. The interface further includes an adhesive material at least partially surrounding the plurality of thermally conductive contacts, and disposed between and bonding the cooling assembly and the at least one electronic device. The adhesive material reduces strain on the plurality of thermally conductive contacts resulting from the coefficient of thermal expansion mismatch between the cooling assembly and the at least one electronic device. The adhesive material comprises a second material, wherein the second material has a second thermal conductivity, and the first thermal conductivity of the first material is greater than the second thermal conductivity of the second material.

In a further aspect, a method is provided for fabricating a thermally conductive composite interface for coupling a cooling assembly and at least one electronic device, wherein the cooling assembly and the at least one electronic device have a coefficient of thermal expansion mismatch. The method includes: providing a plurality of thermally conductive contacts configured for mechanically coupling the cooling assembly and the at least one electronic device, the plurality of thermally conductive contacts comprising a first material, the first material having a first thermal conductivity; and providing an adhesive material at least partially surrounding the plurality of thermally conductive contacts for bonding the cooling assembly to the at least one electronic device, the adhesive material reducing strain on the plurality of thermally conductive contacts resulting from the coefficient of thermal expansion mismatch between the cooling assembly and the at least one electronic device, and wherein the adhesive material comprises a second material, the second material having a second thermal conductivity, and the first thermal conductivity of the first material being greater than the second thermal conductivity of the second material.

Further, additional features and advantages are realized through the techniques of the present invention. Other embodiments and aspects of the invention are described in detail herein and are considered a part of the claimed invention.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1A depicts one embodiment of an electronic assembly wherein thermal grease is employed to couple an electronic device to a cooling assembly;

FIG. 1B is a partial embodiment of another electronic assembly wherein an advanced epoxy interface is employed to couple an electronic device to a lid of the electronic assembly;

FIG. 2 is a partial cross-sectional view of one embodiment of an electronic assembly employing a thermally conductive composite interface coupling an electronic device to a cooling assembly, in accordance with an aspect of the present invention;

FIG. 2A is a partial enlarged view of the electronic assembly of FIG. 2;

FIG. 3 is a plan view of one embodiment of a plurality of thermally conductive contacts arrayed across a surface of an electronic device, in accordance with an aspect of the present invention;

FIG. 3A is a partial enlarged view of the structure of FIG. 3;

FIG. 4 depicts a graph of thermal transfer analysis results for several solder-epoxy composite interfaces constructed in accordance with an aspect of the present invention;

FIG. 5A is a partial cross-sectional view of one manufacturing embodiment for providing an adhesive material surrounding the plurality of thermally conductive contacts of a composite interface, in accordance with an aspect of the present invention;

FIG. 5B depicts an alternate manufacturing embodiment for delivering adhesive material interstitial the cooling assembly and electronic device, and surrounding the plurality of thermally conductive contacts, in accordance with an aspect of the present invention;

FIG. 6 is a partial cross-sectional view of one electronic assembly fabrication embodiment showing delivery of adhesive material interstitial the cooling assembly and electronic device via an opening in the base plate of the cooling assembly, in accordance with an aspect of the present invention; and

FIG. 7 depicts another fabrication embodiment of an electronic assembly wherein adhesive material is provided interstitial the cooling assembly and electronic device via a dedicated boss in the cooling assembly, in accordance with an aspect of the present invention.

### BEST MODE FOR CARRYING OUT THE INVENTION

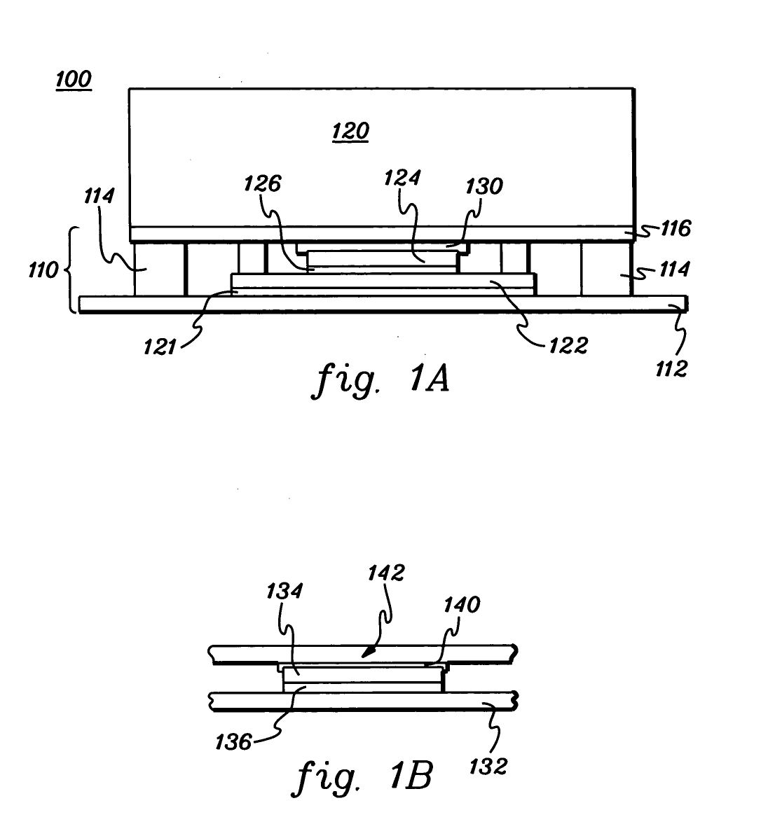

As noted, a thermal grease or an epoxy is conventionally employed as a thermal interface coupling a heat sink or cold plate to an electronic device within an electronic assembly. FIG. 1A depicts one embodiment of an electronic assembly, generally denoted 100, wherein a cooling assembly 120, such as a heat sink with a heat pipe or vapor chamber, is coupled to an electronic module 110. Module 110 includes a printed circuit board 112, side walls 114, and lid 116 within which an integrated circuit chip 124 is packaged. Integrated circuit chip 124 electrically connects (in one example) via a flip chip interface 126 with a substrate 122, and a Ball Grid Array (BGA) 121 is employed to electrically connect substrate 122 to printed circuit board 112. A thermal grease 130 is employed to thermally couple integrated circuit chip 124 to lid 116, and hence to cooling assembly 120.

FIG. 1B depicts a partial embodiment of an electronic assembly wherein an advanced epoxy interface 140 is used to couple an integrated circuit chip 134 to a lid 142, which comprises part of or couples to a cooling assembly (not shown). The integrated circuit chip 134 can electrically connect to a substrate 132 via conventional flip chip interface technology 136.

The thermal transfer performance of the thermal grease of FIG. 1A and the epoxy of FIG. 1B is directly proportional to the thermal conductivity of the material employed, and is inversely proportional to the interface thickness, which is also known as the bond line thickness. Thermal grease interfaces typically have higher thermal conductivity, but also posses a higher bond line thickness, while epoxies typically have a lower thermal conductivity, but the joints can be manufactured with smaller thicknesses. In general, thermal greases show moderate thermal performance, but yield more under stress, while these characteristics are reversed for an epoxy interface. Also, to achieve very small interface thicknesses using an epoxy, while minimizing stresses, it is necessary to bond the electrical device (e.g., integrated circuit chip) to a material that has a thermal expansion coefficient very similar to that of silicon. This limits use of the best performing epoxy interfaces to cooling assembly materials such as silicon carbide, which has a maximum thermal conductivity of 270 W/mK, thus eliminating metals such as copper, which has a higher thermal conductivity.

Generally stated, disclosed herein is a thermally conductive composite interface for coupling an electronic device, such an integrated circuit chip, to a cooling assembly (inclusive of any intermediate structure(s) coupled to a cooling structure or system, such as a thermal spreader or a lid of an electronic module). The thermally conductive composite interface is particularly beneficial when coupling a cooling assembly and electronic module with a significant coefficient of thermal expansion (CTE) mismatch. As the CTE mismatch increases between surfaces of dissimilar materials being joined, the joint shear strain increases proportionally.

As one example, the composite interface includes a plurality of thermally conductive contacts configured for mechanically coupling to and interfacing a cooling assembly and at least one electronic device. The plurality of thermally conductive contacts are fabricated of a first material, which has a first thermal conductivity. The composite interface further includes an adhesive material at least partially surrounding the plurality of thermally conductive contacts for bonding the cooling assembly to the at least one electronic device. The adhesive material reduces strain on the plurality of thermally conductive contacts resulting from the coefficient of thermal expansion mismatch between the cooling assembly and the electronic device. The adhesive material comprises a second material, with the second material having a second thermal conductivity, wherein the first thermal conductivity of the first material is greater than the second thermal conductivity of the second material. As practical examples, the cooling assembly may comprise copper or aluminum, the electronic device silicon, the first material a reflowable metal or metal alloy (such as tin, indium or a solder based material), and the second material an epoxy based material. The composite interface offers high thermal conductance with superior mechanical strength, and allows attachment of silicon based integrated circuit devices to metals such as copper.

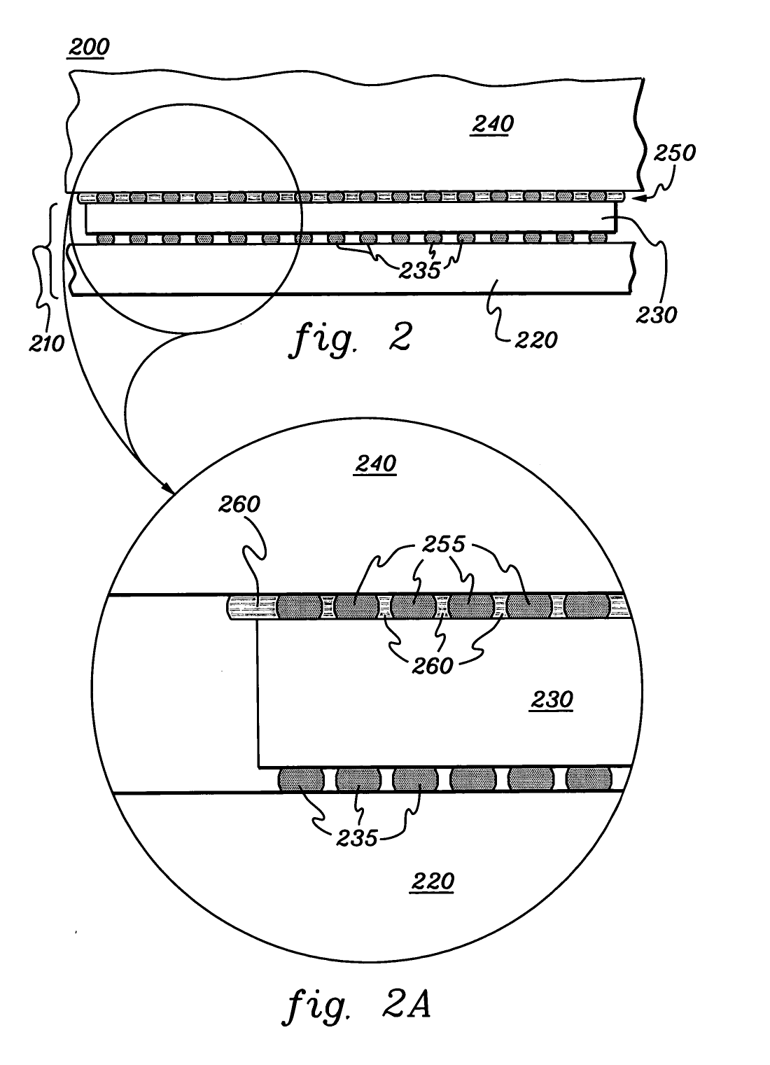

FIGS. 2 & 2A depict one embodiment of an electronic assembly, generally denoted 200, wherein a thermally conductive composite interface 250, in accordance with an aspect of the present invention, is employed to mechanically couple and bond a cooling assembly 240 to an electronic device 230. Cooling assembly 240 could comprise, for example, a heat sink base or a thermal spreader, made of a high thermal conductivity metal or metal alloy, such as copper or aluminum, or a high thermal conductivity ceramic, such as aluminum nitride. In this embodiment, electronic device 230 is electrically connected via solder bumps 235 to wiring of a substrate 220.

As shown, thermally conductive composite interface 250 includes a plurality of thermally conductive contacts 255, which are at least partially, and preferably completely, surrounded by an adhesive material 260. By way of example, the plurality of thermally conductive contacts may comprise a reflowable metal or reflowable metal alloy, while the adhesive material may comprise an epoxy based material. The reflowable metal or reflowable metal alloy is chosen to have a good thermal conductivity and a relatively low melting point, e.g., less than 250° C. (and typically in a range of 100-150° C.). The melting point of the reflowable metal or reflowable metal alloy is preferably significantly lower than that of the solder bumps 235 employed to electrically connect the electronic device to the substrate. This allows the cooling assembly to be mechanically coupled to the electronic device after the electronic device has been electrically connected to the substrate.

In one example, the thermal conductivity of the reflowable metal or reflowable metal alloy is as high as possible. There are a host of metal alloys, for example, of some combination of Sn, Pb, Sb, In, Bi, Ag, Au, etc., that can be employed. Table 1 below compares pure tin, eutectic solder and pure indium to corresponding values for 5/95 solder typically used in a controlled collapsed chip connection (C4).

TABLE 1

| | | | Thermal |
|---|---|---|---|
| | | Melting Point | Conductivity |
| Metal or Metal Alloy | Composition | (Deg. C.) | (W/mK) |
| Pure Tin | 100% Sn | 232 | 63 |
| Eutectic Solder | 37% Sn, 63% Pb | 183 | 51 |
| Pure Indium | 100% In | 157 | 83 |
| 5/95 Solder | 95% Pb, 5% Sn | 312 | 36 |
| (C4 interconnect) | | | |

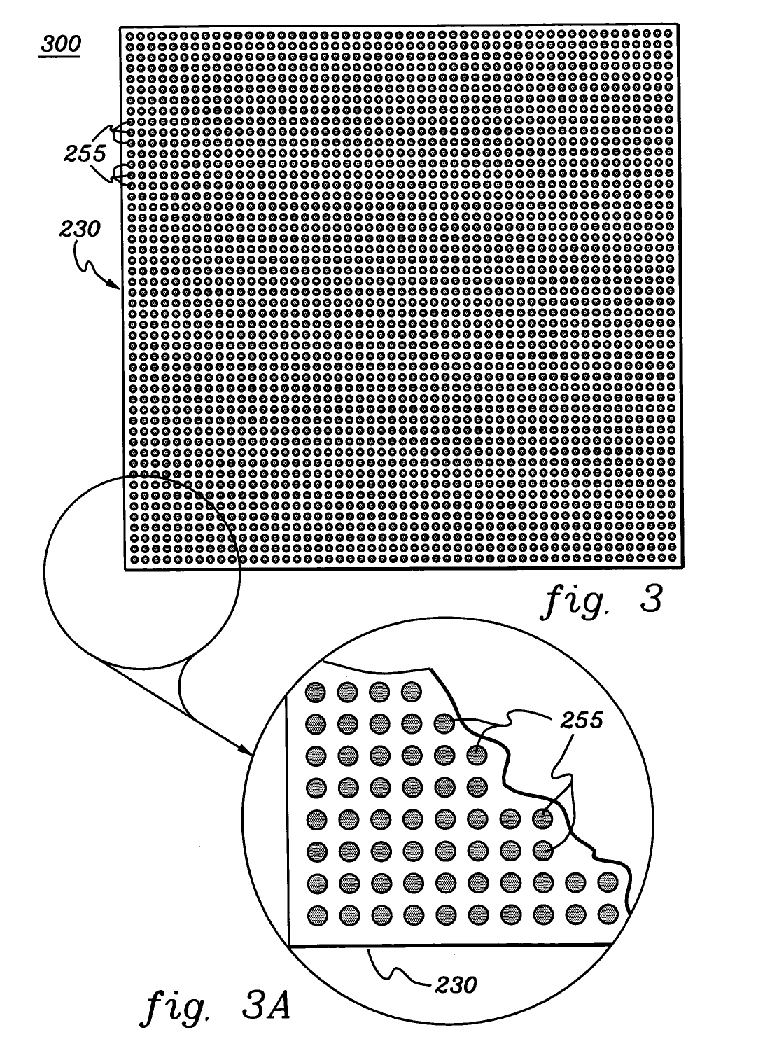

FIGS. 3 & 3A depict one embodiment of the plurality of thermally conductive contacts 255. In this embodiment, a structure 300 is shown wherein the plurality of thermally conductive contacts 255 are arrayed on an exposed planar surface of an electronic device 230 to be cooled. In this example, the contacts comprise thermally conductive balls, such as solder balls. By way of example, the thermally conductive balls may have a diameter in the range of 0.05-0.1 mm, a pitch of 0.1-0.2 mm, and a height of 0.03-0.08 mm. As noted in FIGS. 2 & 2A, these solder balls will be submerged within or surrounded by an adhesive material, such as an epoxy. As one example, there is a maximum number of thermally conductive contacts, for a given fabrication technology, within the composite interface. By maximizing the number of thermally conductive contacts, the number of parallel paths for thermal flow through the interface is also maximized.

The thermally conductive contacts may be evenly or unevenly distributed between the opposing electronic device and the cooling assembly surfaces. For example, if there is an uneven heat flux from the electronic device surfaces, a higher density of thermally conductive contacts may be aligned to the region of higher heat flux, i.e., compared with the region(s) of lower heat flux from the electronic device surface. The thermally conductive contacts provide a superior thermal path for the thermal interface, while the adhesive material acts as a mechanical binding agent for the composite interface. Since the thermally conductive contacts deflect individually rather than as a single body, they allow greater interface “yield” compared with a solid homogeneous interface. This can be important at the edge of the electronic device, where the deflection of the material (electronic device, composite interface, and cooling assembly) would be the largest. The deflection of this assembly typically increases with the distance from the center of the electronic device, which is known as the distance to neutral point (DNP). In addition, the use of thermally conductive contacts fabricated from a metal or metal alloy, provide superior thermal transfer paths compared with an interface comprising only epoxy or thermal grease. Thus, the composite interface disclosed herein is a high performing interface viewed both thermally and mechanically.

As a further enhancement, compressive force may be applied between the electronic device and cooling assembly during reflowing of the reflowable metal or reflowable metal alloy to reduce the gap between the electronic device and cooling assembly (i.e., the thickness of the composite interface). This is contrasted with conventional C4 solder interconnect used to electrically connect an integrated circuit chip to a substrate, wherein there is no mechanical force applied to define the gap or spacing between the integrated circuit chip and the substrate. Rather, surface tension of the reflowed solder determines the gap thickness.

The gap thickness can be mechanically controlled for the thermally conductive composite interface to improve thermal performance of the interface. For example, solid stops or spacers can be employed within the gap in combination with compressive force being applied during reflowing of the metal or metal alloy to define a specific gap thickness between the electronic device and the cooling assembly. Further, applying compressive force to a plurality of thermally conductive contacts during reflowing increases the contact area of the thermal contacts. Since thermal resistance through a metal or metal alloy contact is proportional to the gap thickness of the interface and the contact area of the thermally conductive contacts, thermal resistance through the interface is reduced.

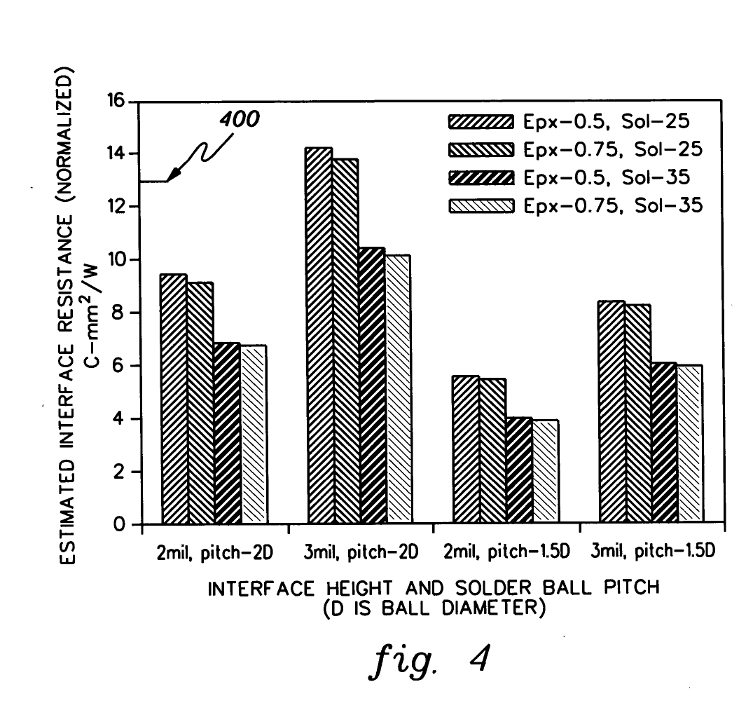

FIG. 4 depicts a graph of thermal transfer analysis results for various solder-epoxy composite interfaces constructed in accordance with an aspect of the present invention. As shown, thermal interface resistance is plotted as a function of contact height and contact pitch, wherein the contacts are assumed to comprise solder balls. Within the graph nomenclature, EPX means epoxy, SOL means solder, and the numbers following EPX and SOL in the legend represent the thermal conductivity of the contact in W/mK. The numbers preceding the “mil” on the X-axis represent the height of the interface and also the diameter of the solder ball, D. The pitch is specified as a multiple of the solder ball diameter, D. Note that this analysis assumes that the solder balls are cylinders for the purposes of heat conduction. Conventional state of the art interfaces typically achieve an interface resistance of about 13 C-mm²/W 400. Most of the composite interfaces depicted in FIG. 4 achieve a reduced interface resistance, and therefore better thermal conductivity than currently employed interfaces.

Fabrication of a composite interface such as disclosed herein can be similar to fabrication methods used in making flip chip electrical interconnect substrates, where a ball grid array is electroplated or deposited via chemical vapor deposition, after which the cooling device is attached or bonded onto the solder balls. Following this operation, epoxy can be back filled into the free space around the plurality of thermal contacts of the interface. As noted, a varying thermal contact pitch can be used to change the thermal and mechanical behavior at different locations of the composite interface, for example, to tailor the interface to meet specific demands of a particular electronic device power map.

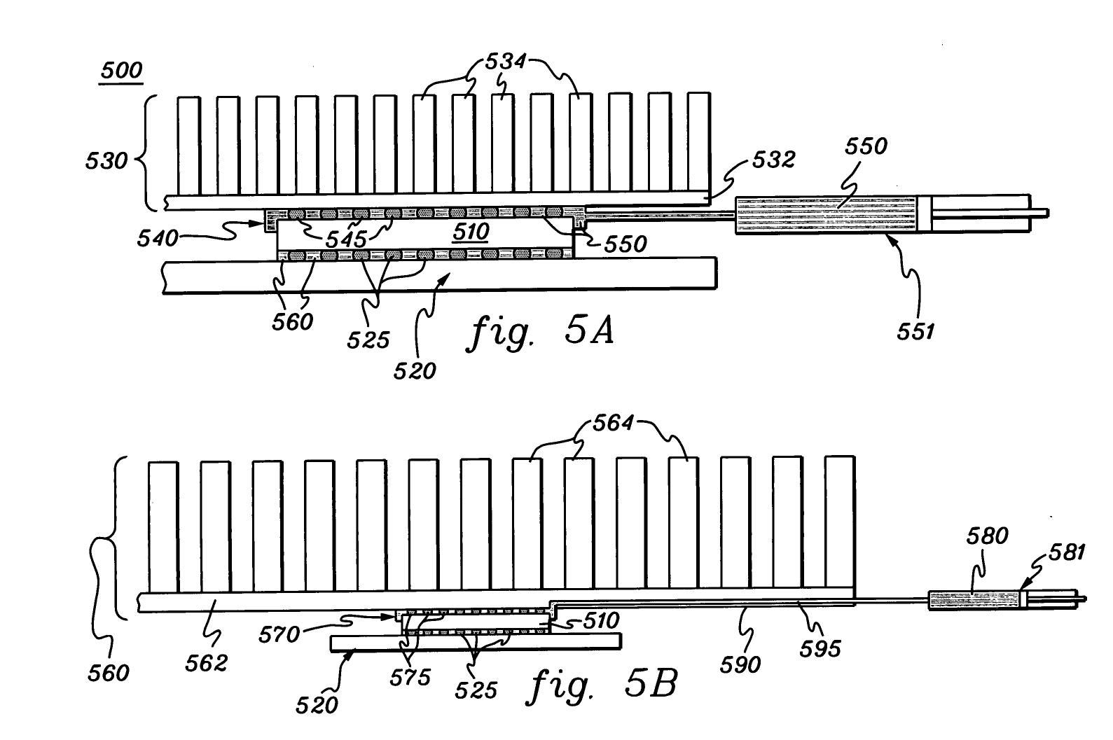

FIGS. 5A-7 depict various methods for injecting a liquid adhesive, such as liquid epoxy, interstitial to the electronic device and cooling assembly so as to surround the plurality of thermally conductive contacts. FIG. 5A depicts one example wherein the cooling assembly, for example, heat sink, vapor chamber, cold plate, etc., is only slightly larger than the footprint area of the electronic device (e.g., integrated circuit chip package). As shown, the electronic assembly 500 includes cooling assembly 530 which is mechanically and thermally coupled to electronic device 510 via a composite interface 540. In this embodiment, the cooling assembly 530 comprises a base plate 532 from which a plurality of pins or fins 534 project. Electronic device 510 is also electrically connected via contacts 525 to a substrate 520. Contacts 525 may also have an adhesive material 560 surrounding them to provide better mechanical connection of the electronic device to the substrate. Electrical connections 525 may comprise controlled collapsed chip connections (C4s), and the substrate may comprise a ceramic or organic substrate having electrical contacts thereon.

In this embodiment, a syringe 551 facilitates injection of adhesive material 550 interstitial the cooling assembly 530 and electronic device 510. The adhesive material is injected along an edge between the top surface of the electronic device and the bottom surface of the cooling assembly, and flows into and fills the free volume between the thermally conductive contacts by capillary action. The procedure can be carried out from any side of the assembly. Once injected, the adhesive material is allowed to cure, thereby forming a rigid bond between the cooling assembly and the electronic device. Once cured, the adhesive material preferably has a high modulus of elasticity to restrain movement of the cooling assembly relative to the electronic device, and thereby reduces strain on the plurality of thermally conductive contacts of the composite interface due to a CTE mismatch between the coupled surfaces.

In FIG. 5B, cooling assembly 560 is assumed to be significantly greater in footprint area than an electronic device 510, which is electrically connected via solder bumps 525 to a substrate 520. In this example the cooling assembly again includes a base plate 562 from which a plurality of fins or pins 564 project. A tunnel-like groove 595 is provided in base plate 562 at the bottom surface of the cooling assembly. The groove is covered with a plate 590 to form a sealed channel through which adhesive material 580 is injected using, for example, a syringe 581. In this example, the covered channel extends to an edge of electronic device 510, thereby allowing adhesive material injected into the covered channel to flow into and fill the free volume between the plurality of thermally conductive contacts by capillary action. This procedure can be carried out from any side, assuming that base plate 562 of the cooling assembly is appropriately configured with the covered channels.

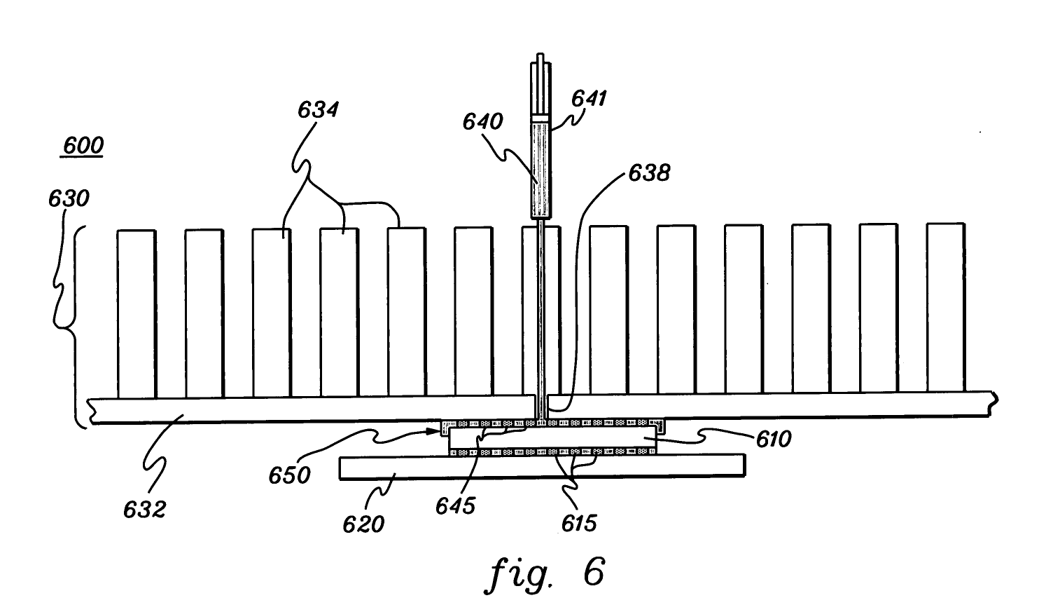

In FIG. 6, an electronic assembly 600 is shown wherein a cooling assembly 630 is thermally and mechanically coupled to an electronic device 610, which is electrically connected via metal contacts 615 to a substrate 620. A composite interface 650 is provided as described herein to couple the cooling assembly to the electronic device. In this example, the cooling assembly again includes a base plate 632 and multiple pins or fins 634 projecting therefrom. In this example, the adhesive material is injected into the free volume between the plurality of thermally conductive contacts via an opening 638 provided in base 632 of the cooling assembly. One or more openings 638 can be provided as needed to inject the adhesive material into the free volume interstitial the cooling assembly and the electronic device. By way of example, these openings could reside between pins 634 of the cooling assembly. As with the embodiment of FIGS. 5A & 5B, adhesive material 640 can be injected using a syringe 641, with the liquid adhesive flowing by capillary action into the free volume between the plurality of thermally conductive contacts.

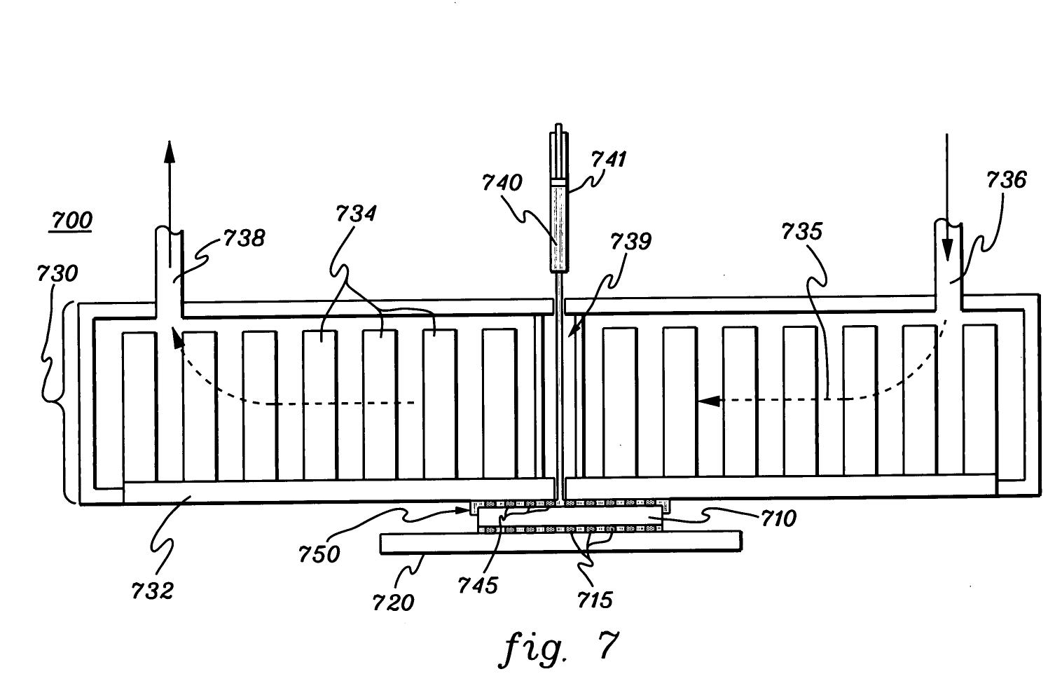

FIG. 7 depicts still another fabrication embodiment, wherein the electronic assembly 700 includes a cooling assembly 730 which comprises a liquid cooled structure such as a cold plate or a micro-channel heat sink. As shown, cooling assembly 730 has a base plate 732 with a plurality of pins or fins 734 projecting into a liquid filled chamber. Liquid 735 enters through one or more inlets 736 and flows through the chamber before being expelled through one or more outlets 738. The cooling assembly is again being thermally and mechanically coupled to an electronic device 710, such as integrated circuit chip, which is electrically connected via electrical contact 715 to a substrate 720. The coupling is achieved using a composite interface such as described hereinabove where a plurality of thermally conductive contacts 745 are provided and are surrounded by an adhesive material 740. The adhesive material may be injected (e.g., using a syringe 741) into the free volume between the thermal contacts. This can be achieved by providing one or more bosses with center opening(s) 739 passing through the cooling assembly 730. The liquid adhesive material is again pulled into the free volumes interstitial the cooling assembly and electronic device surrounding the thermally conductive contacts via capillary action. Surface tension holds the adhesive material in place until the material is cured, thereby achieving the desired high performance bond.

Although preferred embodiments have been depicted and described in detail herein, it will be apparent to those skilled in the relevant art that various modifications, additions, substitutions and the like can be made without departing from the spirit of the invention and these are therefore considered to be within the scope of the invention as defined in the following claims.

1. A thermally conductive composite interface for coupling a cooling assembly and at least one electronic device, the cooling assembly and the at least one electronic device having a coefficient of thermal expansion mismatch, the thermally conductive composite interface comprising:
a plurality of thermally conductive contacts for mechanically coupling the cooling assembly and the at least one electronic device, the plurality of thermally conductive contacts comprising a first material, the first material having a first thermal conductivity; and
an adhesive material at least partially surrounding the plurality of thermally conductive contacts for bonding the cooling assembly to the at least one electronic device when the interface is employed to mechanically couple the cooling assembly and the at least one electronic device, the adhesive material reducing strain on the plurality of thermally conductive contacts resulting from a coefficient of thermal expansion mismatch between the cooling assembly and the at least one electronic device, and wherein the adhesive material comprises a second material, the second material having a second thermal conductivity, and the first thermal conductivity of the first material being greater than the second thermal conductivity of the second material.

2. The thermally conductive composite interface of claim 1, wherein the first material comprises a reflowable metal or reflowable metal alloy and the second material comprises an epoxy based material.

3. The thermally conductive composite interface of claim 2, wherein the first material reflows at a melting point less than 250° C.

4. The thermally conductive composite interface of claim 2, wherein the first material comprises one of pure tin, pure indium or a eutectic solder.

5. The thermally conductive composite interface of claim 2, wherein the cooling assembly comprises one of copper or aluminum, and the at least one electronic device comprises silicon, and wherein the plurality of thermally conductive contacts are disposed in an array to provide multiple parallel thermal paths between the at least one electronic device and the cooling assembly when the thermally conductive composite interface is employed to mechanically couple the cooling assembly and the at least one electronic device.

6. The thermally conductive composite interface of claim 5, wherein the plurality of thermally conductive contacts comprise a plurality of thermally conductive balls, each thermally conductive ball having a diameter less than 0.125 mm.

7. The thermally conductive composite interface of claim 1, wherein density of the plurality of thermally conductive contacts varies within the thermally conductive composite interface.

8. An electronic assembly comprising:
at least one electronic device;
a cooling assembly for the at least one electronic device, wherein the cooling assembly and the at least one electronic device have a coefficient of thermal expansion mismatch; and
a thermally conductive composite interface coupling the cooling assembly and the at least one electronic device, the thermally conductive composite interface comprising:
a plurality of thermally conductive contacts mechanically coupling the cooling assembly and the at least one electronic device, the plurality of thermally conductive contacts comprising a first material, the first material having a first thermal conductivity; and
an adhesive material at least partially surrounding the plurality of thermally conductive contacts, and disposed between and bonding the cooling assembly and the at least one electronic device, the adhesive material reducing strain on the plurality of thermally conductive contacts resulting from the coefficient of thermal expansion mismatch between the cooling assembly and the at least one electronic device, and wherein the adhesive material comprises a second material, the second material having a second thermal conductivity, and the first thermal conductivity of the first material being greater than the second thermal conductivity of the second material.

9. The electronic assembly of claim 8, wherein the first material comprises a reflowable metal or reflowable metal alloy, and the second material comprises an epoxy based material.

10. The electronic assembly of claim 9, wherein the first material reflows at a melting point less than 250° C.

11. The electronic assembly of claim 9, wherein the cooling assembly comprises one of copper or aluminum, and the at least one electronic device comprises silicon, and wherein the plurality of thermally conductive contacts are disposed in an array to provide multiple parallel thermal paths between the at least one electronic device and the cooling assembly.

12. The electronic assembly of claim 11, wherein the plurality of thermally conductive contacts comprise a plurality of thermally conductive balls, each thermally conductive ball having a diameter less than 0.125 mm.

13. The electronic assembly of claim 8, wherein density of the plurality of thermally conductive contacts varies within the thermally conductive composite interface.

14. A method of fabricating a thermally conductive composite interface for coupling a cooling assembly and at least one electronic device, wherein the cooling assembly and the at least one electronic device have a coefficient of thermal expansion mismatch, the method comprising:
providing a plurality of thermally conductive contacts configured for mechanically coupling the cooling assembly and the at least one electronic device, the plurality of thermally conductive contacts comprising a first material, the first material having a first thermal conductivity; and
providing an adhesive material at least partially surrounding the plurality of thermally conductive contacts for bonding the cooling assembly to the at least one electronic device, the adhesive material reducing strain on the plurality of thermally conductive contacts resulting from a coefficient of thermal expansion mismatch between the cooling assembly and the at least one electronic device, and wherein the adhesive material comprises a second material, the second material having a second thermal conductivity, and the first thermal conductivity of the first material being greater than the second thermal conductivity of the second material.

15. The method of claim 14, wherein the first material comprises a reflowable metal or a reflowable metal alloy, and wherein the method further comprises reflowing the reflowable metal or reflowable metal alloy to mechanically couple the plurality of thermally conductive contacts to both the cooling assembly and the at least one electronic device, wherein the plurality of thermally conductive contacts provide multiple thermal paths between the at least one electronic device and the cooling assembly.

16. The method of claim 15, wherein the first material reflows at a melting point less than 250° C.

17. The method of claim 15, wherein the mechanically coupling further comprises applying a force between the cooling assembly and the at least one electronic device during the reflowing to reduce thickness of the plurality of thermal conductive contacts therebetween.

18. The method of claim 15, wherein the adhesive material comprises an epoxy based material, and wherein the providing of the adhesive material comprises injecting the adhesive material in liquid form interstitial the cooling assembly and the at least one electronic device in free space between the plurality of thermally conductive contacts so as to surround the plurality of thermally conductive contacts, and thereafter curing the epoxy based material to obtain a rigid bond between the cooling assembly and the at least one electronic device.

19. The method of claim 18, wherein the injecting of the adhesive material is along at least one edge of the at least one electronic device.

20. The method of claim 18, wherein the injecting of the adhesive material is through at least one opening provided within the cooling assembly.
